(19) United States
(12) Patent Application Publication
(10) Pub. No.: US 2012/0211254 A1
(43) Pub. Date: Aug. 23, 2012

(54) ELECTRONIC DEVICE

(75) Inventor: Masato Miura, Akashi-shi (JP)

(73) Assignee: SANYO ELECTRIC CO., LTD., Osaka (JP)

(21) Appl. No.: 13/400,918

(22) Filed: Feb. 21, 2012

(30) Foreign Application Priority Data
Feb. 21, 2011 (JP) 2011-035047

(51) Int. Cl. H05K 7/00

(52) U.S. Cl. 174/50

(57) ABSTRACT

An electronic device according to the present invention includes: a casing; a containing chamber that is recessed in the casing and configured to contain a component therein; an openable cover that is configured to cover the containing chamber and includes a turnable cover body pivotally supported on the casing, a stopper engaged with a rear face of the cover body, and a slide piece being held between the cover body and the stopper and having an operating portion exposed on a front face of the cover body, the cover being locked at a closure position by a slide operation of the slide piece; and a stopper piece that is configured to project to and retreat from the containing chamber, and is located facing a rear face of the stopper, thus inhibiting the component from falling out.

### CROSS-REFERENCE TO RELATED APPLICATION

This application is based upon and claims the benefit of priority from Japanese Patent Application No. 2011-35047, filed on Feb. 21, 2011, the entire contents of which are incorporated herein by reference.

### FIELD OF THE INVENTION

The present invention relates to an electronic device having a cover for a digital camera or the like.

### DESCRIPTION OF RELATED ART

In a digital camera, a battery containing chamber is recessed in a casing, and further, a stopper piece is disposed in such a manner as to project to or retract from the containing chamber so as to inhibit a battery contained inside of the containing chamber from falling out. Moreover, the containing chamber is openably covered with a battery cover.

The battery cover includes a turnable cover body pivotally supported on the casing, a stopper engaged with the rear face of the cover body, and a slide piece that is held between the cover body and the stopper and has an operating portion exposed on the front face of the cover body. Then, the cover can be locked at a closure position by sliding the slide piece.

However, in the above-described digital camera, when the slide piece of the battery cover is slid, pressing force may act on the cover body, and therefore, the cover body be elastically deformed. Because of this deformation, the stopper may be disengaged from the cover body, and then, there is a possibility that the slide piece may fall from the cover body.

Possible solutions to this would be to more securely engage the stopper with the cover body. However, by doing so, there arises a problem of difficulty in assembling the stopper with respect to the cover body.

An object of the present invention is to provide an electronic device in which a stopper can be readily assembled with respect to a cover body constituting a cover, and further, the possibility of falling of a slide piece from the cover body due to pressing force applied when the slide piece of the cover is operated is reduced.

### SUMMARY OF THE INVENTION

An electronic device according to the present invention includes:

a casing;

a containing chamber that is recessed in the casing and configured to contain a component therein;

an openable cover that is configured to cover the containing chamber and includes a turnable cover body pivotally supported on the casing, a stopper engaged with a rear face of the cover body, and a slide piece being held between the cover body and the stopper and having an operating portion exposed on a front face of the cover body, the cover being locked at a closure position by a slide operation of the slide piece; and

a stopper piece that is configured to project to and retreat from the containing chamber, and is located facing a rear face of the stopper, thus inhibiting the component from falling out.

### BRIEF DESCRIPTION OF THE DRAWINGS

FIG. 1 is a perspective view showing a digital camera with a battery cover locked in one preferred embodiment according to the present invention;

FIG. 2 is a perspective view showing the digital camera with the battery cover unlocked;

FIG. 3 is a perspective view showing the digital camera with the battery cover open;

FIG. 4 is an enlarged cross-sectional view taken along line A-A of FIG. 1;

FIG. 5 is an exploded perspective view showing the battery cover; and

FIG. 6 is another exploded perspective view showing the battery cover, as viewed from a direction different from that of FIG. 5

### DETAILED DESCRIPTION OF PREFERRED EMBODIMENTS

A description will be specifically given below of the present invention that is applied to a digital camera as an electronic device and a battery as a component with reference to the drawings.

As shown in FIGS. 1 to 3, a digital camera in one preferred embodiment according to the present invention is provided with a display 11 and an operating key 12 on the back surface of a casing 1, and a battery cover 2 on the bottom surface of the casing 1.

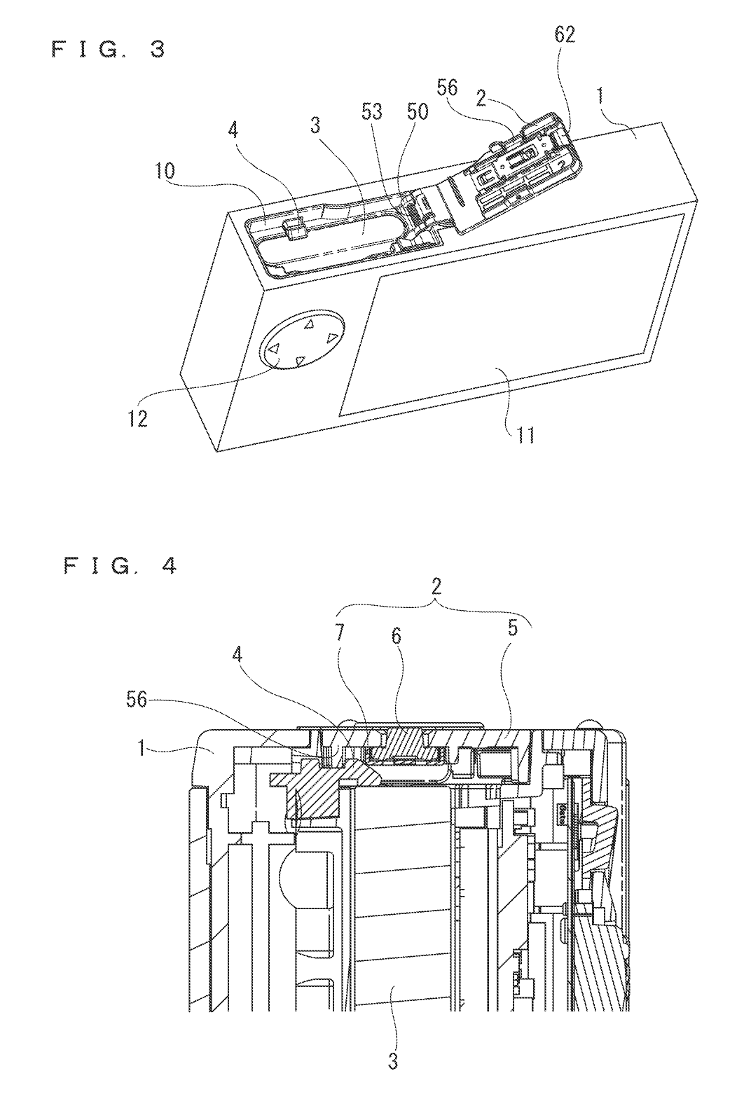

As shown in FIG. 3, recessed in the casing 1 is a containing chamber 10 which is opened or closed by the battery cover 2. A battery 3 is contained as a component inside of the containing chamber 10. The battery 3 is biased in a popping direction by biasing means, not shown.

On the inner wall of the containing chamber 10 is disposed a stopper piece 4 in such a manner as to project to or retract from the containing chamber 10 and to be biased by biasing means, not shown, in a projection direction, so as to inhibit the battery 3 from falling from the containing chamber 10. The stopper piece 4 holds the battery 3 at a containing position inside of the containing chamber 10.

A slope is formed on the tip and upper surface of the stopper piece 4. During inserting the battery 3 into the containing chamber 10, the end of the battery 3 presses the slope, so that the stopper piece 4 retracts against the biasing means, thus allowing the battery 3 to be inserted.

Additionally, the battery cover 2 is pivotally supported on the casing 1 through a pivot 50 disposed at the base end of the battery cover 2, and further, the battery cover 2 is rotationally biased in an opening direction by a torsion spring 53.

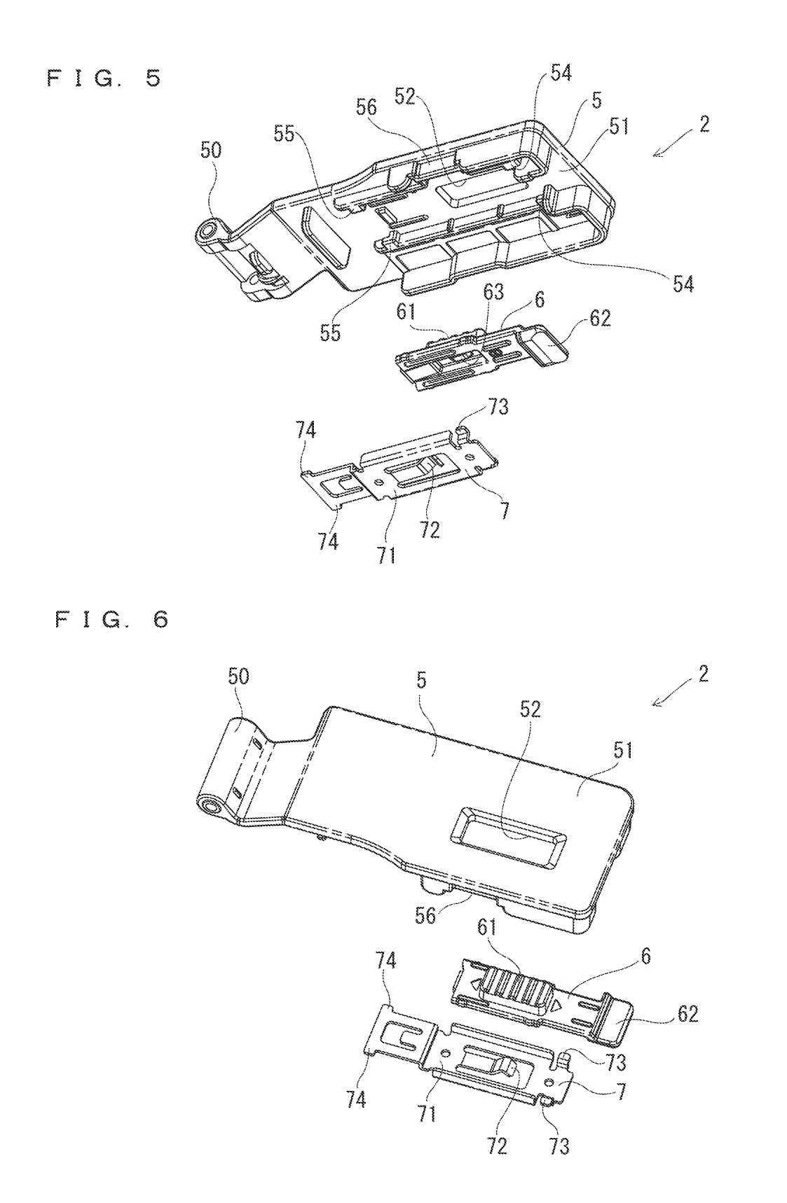

As shown in FIGS. 5 and 6, the battery cover 2 is provided with a cover body 5 having the pivot 50 at the base end, a stopper 7 to be engaged with the rear face of the cover body 5, and a slidable slide piece 6 held between the cover body 5 and the stopper 7.

The cover body 5 is made of a synthetic resin, and further, has an opening 52 in a cover portion 51 for closing the opening formed in the containing chamber 10. On the rear face of the cover portion 51 are formed four engaging pieces 54, 54, 55, and 55 in such a manner as to surround the opening 52.

Moreover, a rib 56, as described below, projects from the rear face of the cover portion 51 of the cover body 5.

The slide piece 6 is made of a synthetic resin, on the upper surface of which an operating portion 61 is provided to be exposed upward from the opening 52 formed in the cover body 5. Furthermore, a tongue piece 62 projects from an end in a slide direction of the slide piece 6.

In addition, a projection 63 is formed on the center of the rear face of the slide piece 6.

The stopper 7 is made of a metal sheet, and further, has a spring 72 at the center of a plate 71. Additionally, four projecting pieces 73, 73, 74, and 74 project outward from the periphery of the plate 71.

In an assembling process of the battery cover 2, the four projecting pieces 73, 73, 74, and 74 of the stopper 7 engage with the four engaging pieces 54, 54, 55, and 55 of the cover body 5 in the state in which the slide piece 6 is held between the cover body 5 and the stopper 7 by utilizing the elastic deformation of the cover body 5 and the stopper 7.

As shown in FIG. 4, the stopper piece 4 is disposed such that its tip is exposed facing the rear face of the stopper 7 constituting the cover 2 in the state in which the tip projects above the upper surface of the battery 3 so as to stop the battery 3 from falling out. Here, a clearance of about 0.1 mm is formed between the tip of the stopper piece 4 and the stopper 7.

In a lock state in which the battery cover 2 is closed and locked at the closure position, as shown in FIG. 1, the tongue piece 62 of the slide piece 6 shown in FIG. 3 engages with an opening edge of the containing chamber 10 of the casing 1.

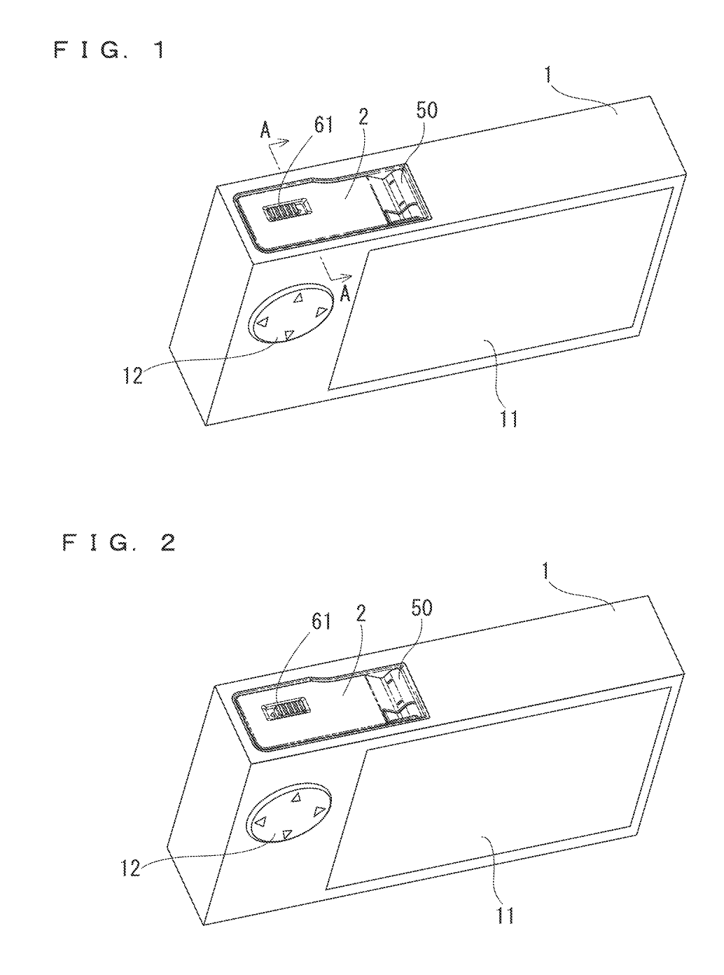

In this state, when the operating portion 61 shown in FIG. 1 slides toward the pivot 50 of the battery cover 2, as shown in FIG. 2, the tongue piece 62 of the slide piece 6 unlocks the battery cover 2. Consequently, the battery cover 2 is automatically opened by the bias of the torsion spring 53, as shown in FIG. 3.

As shown in FIGS. 1 and 2, during the slide of the slide piece 6, the spring portion 72 of the stopper 7 moves beyond the projection 63 of the slide piece 6, thereby giving a clicking feeling in operating the slide piece 6.

When the slide piece 6 is slid, pressing force acts on the cover body 5. However, even when the stopper 7 is displaced toward the containing chamber 10 due to the elastic deformation of the cover body 5, the displacement of the stopper 7 is received by the stopper piece 4 (see FIG. 4), thereby inhibiting the elastic deformation of the cover body 5.

Incidentally, as shown in FIG. 4, even when the stopper 7 presses the slope formed on the tip of the stopper piece 4 so that force in a retract direction acts on the stopper piece 4, the rib 56 projecting from the rear face of the cover body 5 restricts (substantially locks) a retracting motion of the stopper piece 4. As a consequence, the stopper piece 4 securely suppresses the displacement of the stopper 7.

Here, the four projecting pieces 73 and 74 of the stopper 7 engage with the four engaging pieces 54 and 55 of the cover body 5, so that the stopper 7 is engaged with the cover body 5. Since the cover body 5 is hardly elastically deformed during the slide operation of the slide piece 6, there is no possibility of the stopper 7 being disengaged from the cover body 5.

Consequently, the engagement depth of the four projecting pieces 73 and 74 of the stopper 7 into the four engaging pieces 54 and 55 of the cover body 5 may be relatively shallow. As a result, it is easy to work for allowing the four projecting pieces 73 and 74 of the stopper 7 to engage with the four engaging pieces 54 and 55 of the cover body 5 in the assembling process.

Incidentally, the configuration of each of the constituents according to the present invention is not limited to that in the preferred embodiment, and therefore, it may be variously modified within the technical scope of claims. For example, the slide piece 6 is not limited to a slide piece which makes a reciprocating motion on a line, but may be a slide piece which makes a reciprocating motion on an arcuate line.

Moreover, the projection and retract direction of the stopper piece 4 may be the same as the slide direction of the slide piece 6. Alternatively, the stopper piece 4 may make a reciprocating motion on an arcuate line.

Additionally, the present invention is not limited to the battery cover for the digital camera, but may be applied to a cover mechanism for an electronic device having a containing chamber for containing various components therein.

What is claimed is:

1. An electronic device comprising:
a casing;
a containing chamber that is recessed in the casing and configured to contain a component therein;
an openable cover that is configured to cover the containing chamber and includes a turnable cover body pivotally supported on the casing, a stopper engaged with a rear face of the cover body, and a slide piece being held between the cover body and the stopper and having an operating portion exposed on a front face of the cover body, the cover being locked at a closure position by a slide operation of the slide piece; and
a stopper piece that is configured to project to and retreat from the containing chamber, and is located facing a rear face of the stopper, thus inhibiting the component from falling out.

2. The electronic device according to claim 1, wherein the stopper piece is configured to receive displacement of the stopper caused by elastic deformation of the cover body due to pressing force applied to slide the slide piece of the cover.

3. The electronic device according to claim 1, wherein the stopper comprises a plurality of projecting pieces on a plate; and
the cover body has a plurality of engaging pieces on the rear face thereof, elastic deformation of the cover body or the stopper allowing the plurality of projecting pieces to engage with or disengage from the plurality of engaging pieces.

4. The electronic device according to claim 1, wherein a rib that restricts a retracting motion of the stopper piece projects from the rear face of the cover body.
